(19) United States
(12) Patent Application Publication
(10) Pub. No.: US 2026/0239812 A1
(43) Pub. Date: Aug. 13, 2026

(54) LIGHT-EMITTING ELEMENT, LIGHT-EMITTING DEVICE, AND DISPLAY DEVICE

(71) Applicant: Sharp Display Technology Corporation, Kameyama City, Mie (JP)

(72) Inventor: Yukio TAKENAKA, Sakai City, Osaka (JP)

(21) Appl. No.: 19/474,850

(22) PCT Filed: Apr. 14, 2023
(86) PCT No.: PCT/JP2023/015156

§ 371 Date: Oct. 13, 2025

(51) Int. Cl. H10K 50/115; H10K 59/00

(52) U.S. Cl. CPC H10K 50/115; H10K 59/771

(57) ABSTRACT

A light-emitting element includes an anode a cathode and a light-emitting layer between the anode and the cathode. The light-emitting layer includes a first quantum dot a second quantum dot and a semiconductor including a metal element. The semiconductor encompasses the first quantum dot and the second quantum dot. At least part of the semiconductor is formed as a continuous film having an area of 1000 nm² or more in a planar direction orthogonal to a film-thickness direction of the light-emitting layer.

### TECHNICAL FIELD

The disclosure relates to a light-emitting element, and a light-emitting device or a display device including the light-emitting element.

### BACKGROUND ART

PTL 1 discloses a light-emitting element including quantum dots (semiconductor nanoparticles) between electrodes, and describes an illumination device that includes the light-emitting element and emits white light. In particular, PTL 1 describes that an illumination device that emits white light is achieved by mixing and including blue quantum dots, green quantum dots, and red quantum dots in a light-emitting layer of the light-emitting element.

### CITATION LIST

### Patent Literature

PTL 1: WO 2019/078235

### SUMMARY

### Technical Problem

In a case where quantum dots having mutually different luminescent colors are mixed in a light-emitting layer of a light-emitting element as described in PTL 1, energy generated by excitation of a certain quantum dot in the light-emitting layer may be transferred to another quantum dot that emits light having a longer wavelength. In this case, since a quantum dot that emits light of a longer wavelength preferentially emits light, the intensity of light emitted from each quantum dot varies, which may affect a tinge of light obtained from the light-emitting element or shorten the lifetime of a specific quantum dot.

In order to reduce the energy transfer between the quantum dots, it is conceivable to increase a distance between the quantum dots by adding a binder such as a transparent resin to the light-emitting layer. However, since a binder such as a transparent resin generally has a low charge transport efficiency, the luminous efficiency of a light-emitting element including a light-emitting layer containing a binder becomes low.

### Solution to Problem

A light-emitting element according to an aspect of the disclosure includes an anode, a cathode, and a light-emitting layer between the anode and the cathode. The light-emitting layer includes a first quantum dot that emits first light whose light emission central wavelength is a first wavelength, a second quantum dot that emits second light whose light emission central wavelength is a second wavelength longer than the first wavelength, and a semiconductor that encompasses the first quantum dot and the second quantum dot and includes a metal element. At least part of the semiconductor is formed as a continuous film having an area of equal to or larger than 1000 nm² in a planar direction orthogonal to a film-thickness direction of the light-emitting layer.

A method for manufacturing a light-emitting element according to an aspect of the disclosure is a method for manufacturing a light-emitting element including an anode, a cathode, and a light-emitting layer between the anode and the cathode, the method including forming the light-emitting layer, wherein the forming the light-emitting layer includes: preparing a quantum dot dispersion in which a first quantum dot that emits first light whose light emission central wavelength is a first wavelength, a second quantum dot that emits second light whose light emission central wavelength is a second wavelength longer than the first wavelength, and a precursor of a semiconductor including a metal element are dispersed in a solvent; applying the quantum dot dispersion to a substrate; and crystallizing the precursor by heating the applied quantum dot dispersion.

### Advantageous Effects of Disclosure

The disclosure reduces a difference in intensity of light obtained from a plurality of quantum dots having mutually different luminescent colors while suppressing a decrease in luminous efficiency in a light-emitting element including quantum dots in a light-emitting layer.

### BRIEF DESCRIPTION OF DRAWINGS

FIG. 1 is a schematic side cross-sectional view of a light-emitting device according to a first embodiment.

FIG. 2 is an energy band diagram of layers of a light-emitting element according to the first embodiment.

FIG. 3 is a flowchart for describing a method for manufacturing the light-emitting device according to the first embodiment.

FIG. 4 is a schematic process diagram illustrating a ligand substitution process and a quantum dot dispersion preparation process according to the first embodiment.

FIG. 5 is a schematic view illustrating a quantum dot dispersion according to the first embodiment.

FIG. 6 is a process cross-sectional view illustrating part of a method for manufacturing the light-emitting device according to the first embodiment.

FIG. 7 is a schematic side cross-sectional view of a display device according to a second embodiment.

FIG. 8 is a schematic side cross-sectional view of a display device according to a third embodiment.

### DESCRIPTION OF EMBODIMENTS

First Embodiment Embodiments of the disclosure will be described below with reference to the drawings. In each drawing, the same components are denoted by the same reference numerals and signs, and description thereof is omitted.

### Light-Emitting Device

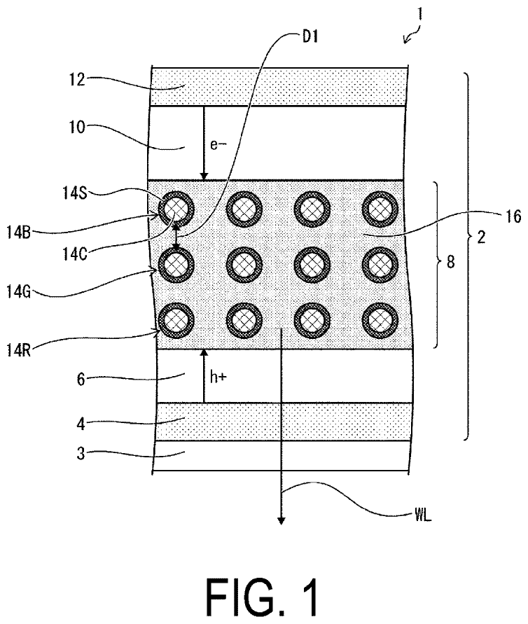

FIG. 1 is a schematic side cross-sectional view of a light-emitting device 1 according to the present embodiment. As illustrated in FIG. 1, the light-emitting device 1 according to the present embodiment includes a light-emitting element 2 and a substrate 3. The light-emitting device 1 has, for example, a structure in which layers of the light-emitting element 2 are layered on the substrate 3, in which a thin film transistor (TFT) (not illustrated) is formed. In the present specification, a direction from the light-emitting element 2 to the substrate 3 of the light-emitting device 1 is referred to as a “downward direction”, and a direction opposite to the downward direction is referred to as an “upward direction”.

The light-emitting element 2 includes an anode 4, a hole transport layer 6, a light-emitting layer 8, an electron transport layer 10, and a cathode 12 layered in this order on the substrate 3. The anode 4 of the light-emitting element 2 formed in a layer above the substrate 3 is electrically connected to the TFT of the substrate 3. Note that the light-emitting element 2 is not limited thereto, and may include the cathode 12, the electron transport layer 10, the light-emitting layer 8, the hole transport layer 6, and the anode 4 layered in this order on the substrate 3.

### Light-Emitting Element: Electrodes and Charge Transport Layers

Hereinafter, a configuration of each layer of the light-emitting element 2 will be described in more detail.

The anode 4 and the cathode 12 include a conductive material and are electrically connected to the hole transport layer 6 and the electron transport layer 10, respectively.

At least one of the anode 4 and the cathode 12 is a transparent electrode through which visible light passes. As the transparent electrode, for example, indium tin oxide (ITO), indium zinc oxide (IZO), ZnO, aluminum-doped zinc oxide (AZO, also referred to as ZAO), boron-doped zinc oxide (BZO), or fluorine-doped tin oxide (FTO) may be used, and may be film-formed by a sputtering method. One of the anode 4 and the cathode 12 may be a light-reflecting electrode. The light-reflecting electrode may contain a metal material, and the metal material is preferably Al, Cu, Au, Ag, or Mg having high reflectivity of visible light, or an alloy thereof. In the present embodiment, a case where the anode 4 is a transparent electrode and the cathode 12 is a light-reflecting electrode will be described as an example.

The hole transport layer 6 is a layer for transporting holes from the anode 4 to the light-emitting layer 8. As the material of the hole transport layer 6, an organic or inorganic material typically employed in a light-emitting element containing quantum dots, an organic EL light-emitting element, or the like can be used. As the organic material of the hole transport layer 6, a conductive compound such as 4,4′-bis(carbazol-9-yl)biphenyl (CBP), polyphenylenevinylene (PPV), a composite (PEDOT-PSS) of poly(3,4-ethylenedioxythiophene) (PEDOT) and polystyrene sulfonate (PSS), poly[(9,9-dioctylfluoreny1-2,7-diyl)-co-(4,4′-(N-4-sec-butylphenyl)diphenylamine)]) (TFB), or polyvinyl carbazole(PVK) can be used. As the inorganic material of the hole transport layer 6, a metal oxide such as a molybdenum oxide, NiO, Cr₂O₃, MgO, MgZnO, LaNiO₃, MoO₃, or WO₃ can be used. In particular, as the material of the hole transport layer 6, a material having a large electron affinity and ionization potential is suitable.

The electron transport layer 10 is a layer for transporting electrons from the cathode 12 to the light-emitting layer 8. As the material of the electron transport layer 10, in addition to TiO2, an organic or inorganic material typically employed in a light-emitting element including quantum dots, an organic EL light-emitting element, or the like can be used. As the organic material of the electron transport layer 10, a conductive compound such as tris(8-quinolinol)aluminum complex (Alq3), bathocuproine (BCP), or (2-(4-biphenylyl)-5-(4-tert-butylphenyl)-1,3,4-oxadiazole) (t-Bu-PBD) can be used. As the inorganic material of the electron transport layer 10, a metal oxide such as ZnO, ZAO, ITO, InGaZnO, or electride can be used. In particular, as the material of the electron transport layer 10, a material having a small electron affinity is suitable.

In the present embodiment, the hole transport layer 6 and the electron transport layer 10 can be formed using the above-described materials by a vacuum deposition method, a sputtering method, a coating formation method using a colloidal solution, or the like. The light-emitting element 2 may include a hole injection layer between the anode 4 and the hole transport layer 6, and may include an electron injection layer between the cathode 12 and the electron transport layer 10. The light-emitting element 2 may further include an intermediate layer such as a charge blocking layer between the hole transport layer 6 and the light-emitting layer 8 or between the electron transport layer 10 and the light-emitting layer 8. Any of the hole injection layer, the electron injection layer, and the intermediate layer may be formed by the same method as the hole transport layer 6 or the electron transport layer 10.

### Light-Emitting Element: Quantum Dots

In the present embodiment, the light-emitting layer 8 includes, as the quantum dots, blue quantum dots 14B as first quantum dots, green quantum dots 14G as second quantum dots, and red quantum dots 14R as third quantum dots. The light-emitting layer 8 contains a sulfide semiconductor 16 as a semiconductor containing a metal element.

Holes from the anode 4 and electrons from the cathode 12 are injected into the quantum dots included in the light-emitting layer 8, and each quantum dot is excited by an exciton generated by recombination of the holes and the electrons and emits light by transition to a ground state. For example, the blue quantum dot 14B is a quantum dot having a core/shell structure including a core 14C and a shell 14S formed around the core 14C. The green quantum dot 14G and the red quantum dot 14R may have the same configuration as the blue quantum dot 14B except for the wavelengths of light emitted from the cores, and are, for example, quantum dots having the core/shell structure. Hereinafter, unless otherwise specified, the blue quantum dot 14B is cited and described as an example.

In the present embodiment, recombination between an electron and a hole injected into the blue quantum dot 14B occurs mainly in the core 14C. The shell 14S has functions of suppressing generation of a defect, a dangling bond, or the like in the core 14C and reducing recombination of carriers through a deactivation process.

In the blue quantum dot 14B, the respective materials of the core 14C and the shell 14S may include materials used for the core material and the shell material of a quantum dot having a typically known core/shell.

For example, in the present embodiment, the material of the shell 14S includes ZnSₓSe₁₋ₓ where 0≤x≤1 is satisfied. Specifically, the blue quantum dot 14B may be a semi-Cd-based conductor nanoparticle including CdSe in the core 14C and ZnS in the shell 14S. Alternatively, the blue quantum dot 14B may be a semi-Cd-based conductor nanoparticle including CdSe in the core 14C and ZnSe in the shell 14S.

In addition, the blue quantum dot 14B may include CdSe/CdS, InP/ZnS, ZnSe/ZnS, CIGS/ZnS, or the like as the core/shell structure. Note that the shell 14S may be formed of a plurality of layers including a plurality of materials different from each other.

The core 14C of the blue quantum dot 14B is a light-emitting material that has a valence band level and a conduction band level and emits light through recombination between holes in the valence band level and electrons in the conduction band level. Since light emitted from the blue quantum dot 14B has a narrower spectrum due to a quantum confinement effect, it is possible to achieve light emission with relatively deep chromaticity.

The quantum dots in the light-emitting layer 8 do not need to be regularly arranged as illustrated in FIG. 1, and may be randomly included in the light-emitting layer 8. The film thickness of the light-emitting layer 8 may be approximately in a range from 1 nm to 100 nm.

The blue quantum dot 14B emits blue light as first light, the green quantum dot 14G emits green light as second light, and the red quantum dot 14R emit red light as third light. In the disclosure, the blue light refers to light with a light emission central wavelength in a range from 380 nm to 490 nm, the green light refers to light with a light emission central wavelength in a range from 490 nm to 570 nm, and the red light refers to light with a light emission central wavelength in a range from 570 nm to 750 nm.

For example, the light emission central wavelength of the blue light emitted by the blue quantum dot 14B is defined as a first wavelength, the light emission central wavelength of the green light emitted by the green quantum dot 14G is defined as a second wavelength, and the light emission central wavelength of the red light emitted by the red quantum dot 14R is defined as a third wavelength. In this case, the second wavelength is longer than the first wavelength, and the third wavelength is longer than the second wavelength.

In the light-emitting device 1, for example, a voltage is applied to the anode 4 via a TFT of the substrate 3 while maintaining a potential of the cathode 12, and holes and electrons are injected into the light-emitting layer 8, thereby causing the light-emitting layer 8 to emit light. In particular, the light-emitting device 1 extracts, from the light-emitting layer 8, white light WL including the blue light from the blue quantum dots 14B, the green light from the green quantum dots 14G, and the red light from the red quantum dots 14R, to the side of the anode 4 as a transparent electrode. In this case, the light-emitting device 1 may extract light from the light-emitting layer 8 to the outside through gaps between members that do not transmit light, such as electrodes of the TFT of the substrate 3.

As described above, the light-emitting device 1 according to the present embodiment extracts the white light WL from the light-emitting element 2 to the outside. The light-emitting device 1 may be, for example, an illumination device, a display device, or a backlight unit. In the case where the light-emitting element 2 includes the anode 4 as a reflective electrode and the cathode 12 as a transparent electrode, the light-emitting device 1 may extract the white light WL from the light-emitting element 2 to the side opposite to the substrate 3.

Here, an optical spectrum of the white light WL emitted from the light-emitting layer 8 by the voltage application of any of the light-emitting elements 2 includes an optical spectrum of visible light. In the present embodiment, an integral value of the optical spectrum of the white light WL in a wavelength range of each of the blue light, the green light, and the red light is 5% or more and 30% or less, 55% or more and 75% or less, and 15% or more and 35% or less of an integral value of the optical spectrum of the white light WL in the wavelength range of the visible light.

To be more specific, for example, the value obtained by integrating the optical spectrum of the white light WL from the light-emitting layer 8 obtained by applying a voltage to the anode 4 of the light-emitting element 2 in the wavelength range from 380 nm to 750 nm is defined as a total integral value of the optical spectrum of the white light WL in the wavelength range of the visible light. In this case, the integral value of the optical spectrum of the white light WL in the wavelength range from 380 nm to 490 nm is 5% or more and 30% or less of the total integral value. The integral value of the optical spectrum of the white light WL in the wavelength range from 490 nm to 570 nm is 55% or more and 75% or less of the total integral value. The integral value of the optical spectrum of the white light WL in the wavelength range from 570 nm to 750 nm is 15% or more and 35% or less of the total integral value.

In general, human visibility varies depending on the wavelength of light, and the white light WL having the above-described difference in components is perceived as natural white light such as sunlight more than light in which the respective components of the blue light, green light, and red light are the same. Therefore, with the above configuration, the light-emitting device 1 can extract natural white light WL closer to sunlight or the like from the light-emitting element 2.

The numbers of particles of the blue quantum dots 14B, the green quantum dots 14G, and the red quantum dots 14R are 5% or more and 30% or less, 55% or more and 75% or less, and 15% or more and 35% or less, respectively, of the total number of particles of the quantum dots in the light-emitting layer 8. Thus, the light-emitting device 1 can extract white light satisfying the above-described conditions from the light-emitting element 2 only by causing the quantum dots to emit light at substantially the same intensity. Therefore, with the above configuration, the light-emitting device 1 can extract natural white light WL closer to sunlight or the like from the light-emitting element 2 by a simpler configuration.

The wavelength of light emission from each of the quantum dots can be controlled by the particle size of the quantum dots. In particular, each quantum dot has a core/shell structure, and therefore, the wavelength of the emitted light can be controlled by controlling the particle size of the core. For example, the particle size of the core 14C of the blue quantum dot 14B may be larger than the particle size of the core of each of the green quantum dot 14G and the red quantum dot 14R. The overall particle size of each of the quantum dots can be controlled by controlling the film thickness of the shell of each quantum dot, and may be, for example, approximately in a range from 1 nm to 100 nm.

### Light-Emitting Element: Semiconductor

The sulfide semiconductor 16 according to the present embodiment includes, at any position in the film-thickness direction of the light-emitting layer 8, a continuous film having an area of 1000 nm² or more in a planar direction orthogonal to the above film-thickness direction. To rephrase, at least part of the sulfide semiconductor 16 is formed as a continuous film having an area of 1000 nm² or more in the planar direction orthogonal to the film-thickness direction of the light-emitting layer 8 at any position in the film-thickness direction thereof. In the light-emitting layer 8, the continuous film of the sulfide semiconductors 16 encompasses the blue quantum dots 14B, the green quantum dots 14G, and the red quantum dots 14R.

In the disclosure, the expression “the continuous film encompasses each quantum dot” means that, for example, the continuous film covers part or the whole of the surface of each quantum dot. The continuous film may be a single film that is not separated by a material other than the continuous film, or may be in the form of an integral film coupled by chemical bonding of a material constituting the continuous film without interruption. For example, the continuous film is formed to partially or completely fill a space formed between the plurality of quantum dots encompassed by the continuous film. In the disclosure, the light-emitting layer 8 may have a void. The plurality of quantum dots encompassed by the continuous film may exist at intervals between each other. For example, when 60% or more of each surface of the quantum dot is in contact with the continuous film of the sulfide semiconductor 16 in 80% or more of the quantum dots included in the light-emitting layer 8, it can be said that the sulfide semiconductor 16 encompasses the quantum dots in the light-emitting layer 8. For example, in the light-emitting layer 8, the sulfide semiconductor 16 may be formed in such a manner as to fill the spaces formed between the blue quantum dots 14B, the green quantum dots 14G, and the red quantum dots 14R.

When the light-emitting layer 8 includes the sulfide semiconductor 16 of the continuous film encompassing the plurality of quantum dots, the sulfide semiconductor 16 is located between the plurality of quantum dots in the light-emitting layer 8, and thus, the distance between two quantum dots adjacent to each other is increased.

In general, energy transfer from an excited quantum dot to another quantum dot is carried out dominantly by energy transfer by the Förster mechanism. On the other hand, the probability of occurrence of energy transfer between two objects by the Förster mechanism is inversely proportional to the sixth power of the distance between the two objects. Because of this, when the distance between two quantum dots increases, the probability of occurrence of energy transfer by the Förster mechanism between the two quantum dots decreases rapidly.

Therefore, the light-emitting element 2 including the light-emitting layer 8, in which the distance between two quantum dots adjacent to each other is large, efficiently reduces the energy transfer between the quantum dots.

On the other hand, a semiconductor containing a metal element has a higher carrier concentration and a higher carrier mobility than a binder such as a transparent resin, and thus, has a high electron transport property and a high hole transport property. In particular, the sulfide semiconductor 16 containing a metal element particularly has a high electron transport property and a high hole transport property. Due to this, the light-emitting layer 8 improves the efficiency of electron injection and the efficiency of hole injection into each quantum dot as compared with the case where a binder such as a transparent resin is included between the plurality of quantum dots. Accordingly, the light-emitting element 2 improves the efficiency of carrier injection into the light-emitting layer 8 and lowers a drive voltage required for light emission by the carrier injection.

In addition, a semiconductor containing a metal element is unlikely to allow penetration of foreign matters such as moisture and has high thermal conductivity, as compared with a transparent resin or the like. Because of this, the light-emitting layer 8 containing the above-mentioned semiconductor encompassing the quantum dots can reduce deterioration of the quantum dots due to penetration of foreign matters from the outside of the light-emitting layer 8 or heat generation. Therefore, the light-emitting element 2 reduces deterioration of the quantum dots of the light-emitting layer 8 during the manufacturing process or when being used, and improves the luminous efficiency.

Thus, the light-emitting element 2 reduces a difference in intensity of light obtained from the plurality of quantum dots having mutually different luminescent colors while suppressing the decrease in luminous efficiency. Therefore, the light-emitting device 1 including the light-emitting element 2, while achieving power saving or a long lifetime, reduces a situation in which the tinge of light obtained from the light-emitting element 2 is biased toward light from a certain quantum dot.

In particular, the light-emitting element 2 according to the present embodiment includes the blue quantum dots 14B, green quantum dots 14G, and red quantum dots 14R, and emits the white light WL. With the above configuration, the light-emitting element 2 reduces the energy transfer from the blue quantum dots 14B to the green quantum dots 14G, and reduces the energy transfer from the blue quantum dots 14B or green quantum dots 14G to the red quantum dots 14R. Accordingly, the light-emitting element 2 reduces a situation in which the intensity of the white light WL for each wavelength is biased due to the energy transfer described above toward the red light having the longest wavelength among the light emitted from the light-emitting layer 8, and thereby emits the white light WL having higher quality.

The sulfide semiconductor 16 may contain, for example, at least one of zinc sulfide, gallium sulfide, or magnesium sulfide. With this, the light-emitting element 2 enhances the charge transport property of the sulfide semiconductor 16 in the light-emitting layer 8, and further improves the luminous efficiency.

However, the sulfide semiconductor 16 according to the present embodiment is not limited thereto as long as the injection of carriers from each charge transport layer to the quantum dots of the light-emitting layer 8 and the transmitting of visible light in the light-emitting layer 8 are not obstructed. For example, the sulfide semiconductor 16 may be a sulfide semiconductor mainly containing a sulfide of Zn and a sulfide of an additive metal made of at least one of Cd, Sn, Mn, Ga, In, Ce, or Cu. For example, the sulfide semiconductor 16 may contain ZnS, ZnTeS, ZnMgS₂, MgS, Ga₂S₃, ZnGa₂S₄, or MgGa₂S₄.

The light-emitting layer 8 may further include, as a semiconductor containing a metal element, a semiconductor other than the sulfide semiconductor 16. For example, the semiconductor included in the light-emitting layer 8 may contain metal halide composed of a metal element and a halogen element. In particular, the semiconductor in the light-emitting layer 8 may contain the metal halide and a metal sulfide. Examples of the metal halide as a semiconductor include copper iodide, silver iodide, CsPbCl₃, CsPbBr₃, and CsPbI₃. For example, the semiconductor including a metal element in the light-emitting layer 8 may contain a metal sulfide and metal halide composed of a metal element and a halogen element.

The light-emitting layer 8 may contain the sulfide semiconductor 16 in an amount of 4% or more and 20% or less by volume. When the light-emitting layer 8 contains the sulfide semiconductor 16 in the amount of 4% or more by volume, the light-emitting element 2 can have a sufficiently large distance between the plurality of quantum dots of the light-emitting layer 8, and can sufficiently reduce the energy transfer between the plurality of quantum dots. In addition, when the light-emitting layer 8 contains the sulfide semiconductor 16 in the amount of 20% or less by volume, the light-emitting element 2 can suppress a decrease in injection efficiency of carriers from each charge transport layer to the quantum dots of the light-emitting layer 8, and can suppress a decrease in luminous efficiency.

From the viewpoint of more efficiently reducing the energy transfer between the plurality of quantum dots, an average distance D1 between the blue quantum dot 14B and the green quantum dot 14G adjacent to each other in the light-emitting layer 8 may be equal to or longer than 1 nm. An average distance between the blue quantum dot 14B and the red quantum dot 14R adjacent to each other and an average distance between the green quantum dot 14G and the red quantum dot 14R adjacent to each other may also be equal to or longer than 1 nm. In the disclosure, the average distance between the quantum dots adjacent to each other in the light-emitting layer 8 is an average of distances between the cores of 20 quantum dots adjacent to each other in a space including 20 or more quantum dots in the light-emitting layer 8.

### Light-Emitting Element: Band Gap

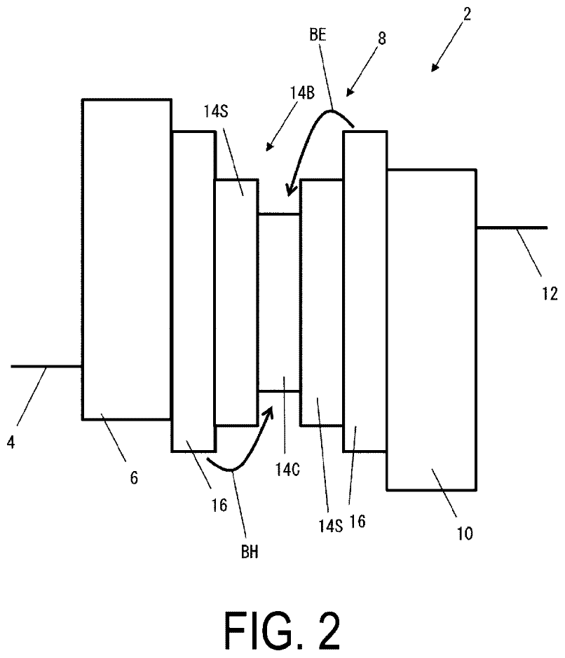

A relationship of band gaps of the layers in the light-emitting element 2 will be described with reference to FIG. 2. FIG. 2 is a schematic energy band diagram of the layers of the light-emitting element 2 according to the present embodiment. In FIG. 2, the respective Fermi levels of the anode 4 and the cathode 12 are illustrated. FIG. 2 illustrates the respective band gaps of the hole transport layer 6, the light-emitting layer 8, and the electron transport layer 10. In particular, in the band gap of the light-emitting layer 8 depicted in FIG. 2, a band gap between the core 14C and the shell 14S of the blue quantum dot 14B among the quantum dots contained in the light-emitting layer 8, and a band gap of the sulfide semiconductor 16 are indicated.

In FIG. 2, assume that the vacuum level is located at the upper side of the paper surface, in other words, the energy is higher at the upper side of the paper surface. In this case, the electron affinity of each layer of the light-emitting element 2 corresponds to the energy from the vacuum level to the upper end of the layer, and the ionization potential of each layer of the light-emitting element 2 corresponds to the energy from the vacuum level to the lower end of the layer. In general, in a semiconductor, the larger the band gap, the smaller the electron affinity and the larger the ionization potential.

In the present embodiment, it is preferable that the band gap of the sulfide semiconductor 16 be larger than the band gap of the core 14C of the blue quantum dot 14B. In particular, it is preferable that the electron affinity of the sulfide semiconductor 16 be smaller than that of the core 14C and the ionization potential of the sulfide semiconductors 16 be larger than that of the core 14C.

In general, in a charge injection type light-emitting element, an electron injection barrier when injecting electrons from a first layer to a second layer adjacent to the first layer is equivalent to energy obtained by subtracting the electron affinity of the second layer from the electron affinity of the first layer. Further, in general, in the charge injection type light-emitting element, a hole injection barrier when injecting holes from the first layer to the second layer adjacent to the first layer is equivalent to energy obtained by subtracting the ionization potential of the first layer from the ionization potential of the second layer.

Thus, an electron injection barrier BE from the sulfide semiconductor 16 to the core 14C is equivalent to energy obtained by subtracting the electron affinity of the core 14C from the electron affinity of the sulfide semiconductor 16. Further, a hole injection barrier BH from the sulfide semiconductor 16 to the core 14C is equivalent to energy obtained by subtracting the ionization potential of the sulfide semiconductor 16 from the ionization potential of the core 14C.

By covering the quantum dots 14B, 14G, and 14R with the sulfide semiconductor, the voltage required for injecting carriers into the quantum dots 14B, 14G, and 14R is lowered as compared with the case where the quantum dots 14B, 14G, and 14R are covered with an insulating polymer. Thus, the light-emitting element 2 improves the efficiency of electron injection and hole injection from the sulfide semiconductor 16 into the core 14C of the quantum dot, and lowers the voltage required for light emission.

In addition, since the band gap of the sulfide semiconductors 16 is larger than the band gap of the core 14C, the energy of an exciton generated in the core 14C is unlikely to diffuse into the sulfide semiconductor 16. With this, the light-emitting element 2 further improves light-emission characteristics of the blue quantum dots 14B.

In general, as the wavelength of light emitted from a quantum dot is longer, the band gap of the core of the quantum dot becomes smaller. Accordingly, when the band gap of the sulfide semiconductor 16 is larger than the band gap of the core 14C of the blue quantum dot 14B, the band gap of the sulfide semiconductor 16 is larger than the band gap of the core of each of the green quantum dot 14G and the red quantum dot 14R.

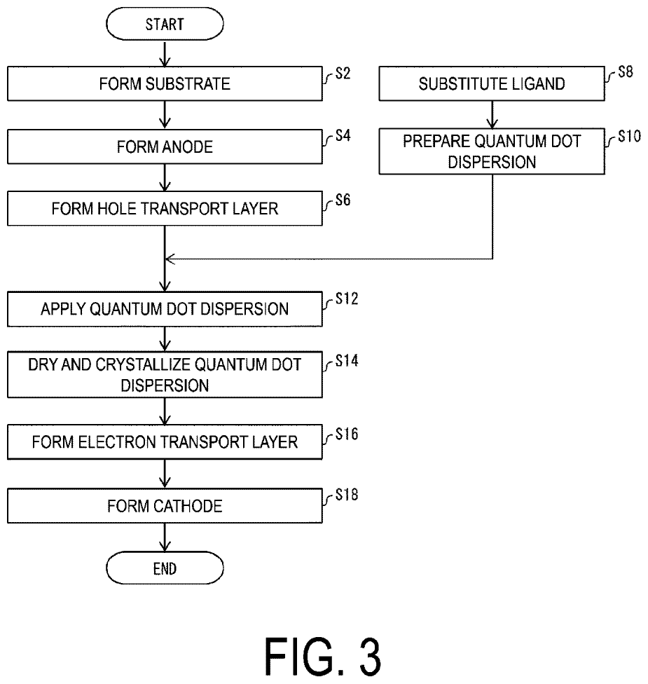

Method for Manufacturing Light-Emitting Device: Up to Forming Hole Transport Layer A method for manufacturing the light-emitting device 1 as an example of a method for manufacturing the light-emitting device according to the present embodiment will be described with reference to FIG. 3. FIG. 3 is a flowchart for describing the method for manufacturing the light-emitting device 1 according to the present embodiment.

In the method for manufacturing the light-emitting device 1 according to the present embodiment, the substrate 3 is formed first (step S2). The substrate 3 may be formed by forming a TFT on a glass substrate while being aligned to a position where the anode 4 of the light-emitting element 2 is formed.

Next, the anode 4 is formed (step S4). The anode 4 may be formed by film-forming a conductive material by using, for example, a sputtering method as described above. Next, the hole transport layer 6 is formed (step S6). As described above, the hole transport layer 6 may be formed by, for example, a vacuum deposition method, a sputtering method, or a coating formation method using a colloidal solution.

### Method for Manufacturing Light-Emitting Device: Preparation of Quantum Dot Dispersion

Next, the light-emitting layer 8 is formed. In the present embodiment, an example will be described in which a quantum dot dispersion containing the quantum dots is prepared by the time when step S6 is completed, and the quantum dot dispersion is applied and then dried to obtain the light-emitting layer 8.

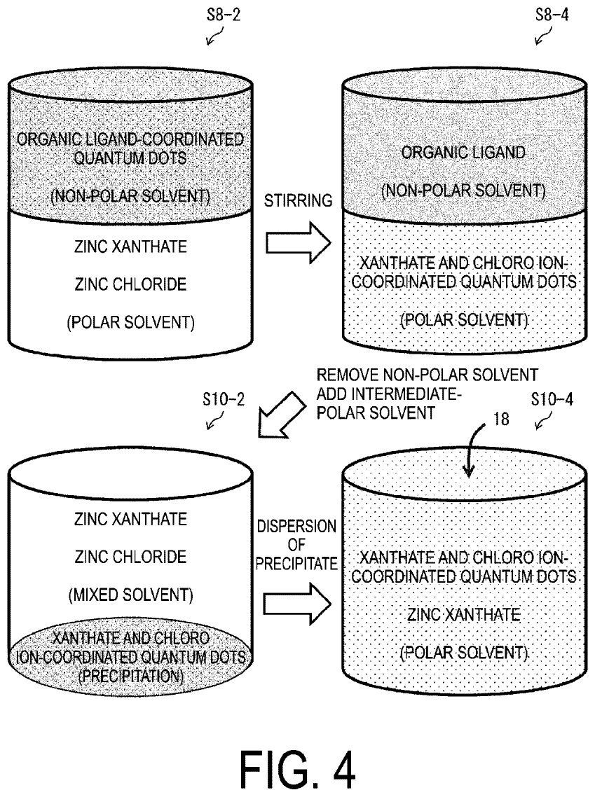

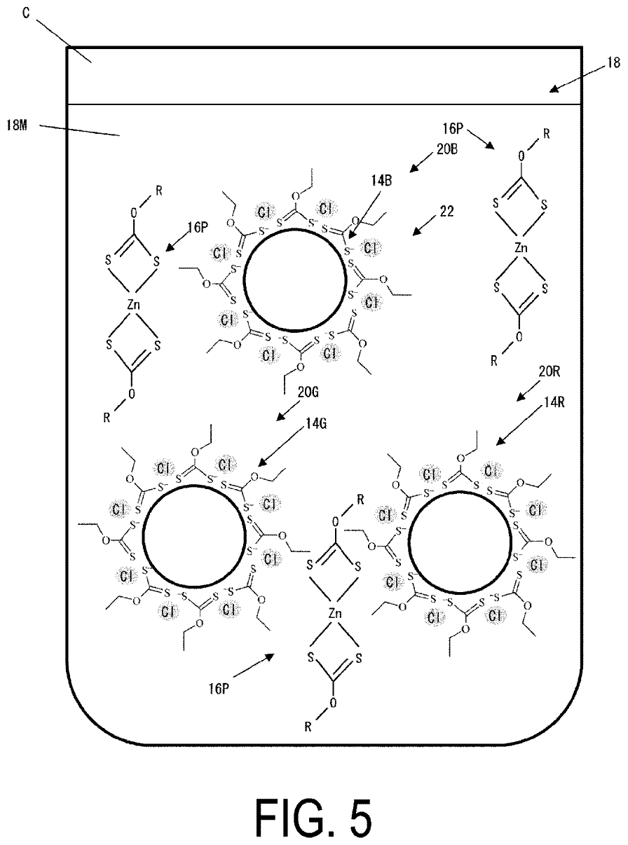

In the present embodiment, for example, as a pre-process of preparing the quantum dot dispersion, ligands coordinated to the blue quantum dots 14B, the green quantum dots 14G, and the red quantum dots 14R are substituted (step S8). Next, the quantum dot dispersion containing the blue quantum dots 14B, the green quantum dots 14G, and the red quantum dots 14R, in which the coordinated ligands are substituted, is prepared (step S10). Step S8 and step S10 will be described in more detail with reference to FIGS. 4 and 5. FIG. 4 is a process diagram illustrating step S8 and step S10 according to the present embodiment, and FIG. 5 is a schematic view illustrating a quantum dot dispersion 18 according to the present embodiment prepared in a container C. In FIG. 5, the scale of each material contained in the quantum dot dispersion 18 is enlarged.

In step S8, first, a first solution containing the blue quantum dots 14B, the green quantum dots 14G, and the red quantum dots 14R in an amount of 1 mg/mL is prepared. The first solution is prepared in such a manner that, for example, as illustrated in step S8-2 of FIG. 4, the blue quantum dots 14B, the green quantum dots 14G, and the red quantum dots 14R, to which non-polar organic ligands are coordinated, are dispersed in a non-polar solvent such as hexane. In step S8, a 0.1 mol/L solution in which a xanthate source is dissolved in a polar solvent and a 0.2 mol/L solution in which a halogen source is dissolved in a polar solvent are mixed to prepare a second solution. In the present embodiment, an example in which the xanthate source is ethyl zinc xanthate, the halogen source is zinc chloride, and the polar solvent is N-Methylformamide (NMF) will be described. Note that, however, the halogen source may be, for example, another halogen compound, and the halogen compound may be a halide metal or halide ammonium. The xanthate source and the halogen source may contain the same metal element.

Next, the first solution and the second solution described above are mixed, and in a state where the layer of the first solution as an upper layer and the layer of the second solution as a lower layer are separated, the mixture is vigorously stirred for 24 hours in the container into which a stir bar is put. As a result, as illustrated in step S8-4 of FIG. 4, the blue quantum dots 14B, the green quantum dots 14G, and the red quantum dots 14R are transferred from the layer of the first solution to the layer of the second solution, and ethyl xanthate and chloro ions are coordinated to the respective quantum dots. In this manner, the substitution of the ligands coordinated to the blue quantum dots 14B, the green quantum dots 14G, and the red quantum dots 14R is completed.

Next, in step S10, the first solution is removed by removing the non-polar solvent together with the organic ligands from the mixed solution of the first and second solutions, and an intermediate-polar solvent such as ethyl acetate is added to the remaining second solution. With this, as illustrated in step S10-2 of FIG. 4, the blue quantum dots 14B, the green quantum dots 14G and the red quantum dots 14R, and ethyl xanthate and chloro ions coordinated to these quantum dots precipitate. On the other hand, zinc chloride and ethyl zinc xanthate do not precipitate and remain in a mixed solvent in which the polar solvent and the intermediate-polar solvent are mixed.

Next, a predetermined amount of the precipitate mentioned above and a predetermined amount of ethyl zinc xanthate as a precursor of the sulfide semiconductor 16 described below are dispersed in a polar solvent such as N, N-dimethylformamide (DMF). As described above, as illustrated in step S10-4 of FIG. 4, the quantum dot dispersion 18 containing the blue quantum dots 14B, the green quantum dots 14G, the red quantum dots 14R, and the ethyl zinc xanthate at a desired concentration is prepared.

As illustrated in FIG. 5, the quantum dot dispersion 18 prepared by the above-described method includes a solvent 18M, a precursor 16P of the sulfide semiconductor 16 dispersed in the solvent 18M, a blue quantum dot structure 20B, a green quantum dot structure 20G, and a red quantum dot structure 20R.

The solvent 18M may include, for example, in addition to the above-described DMF, at least one kind selected from the group consisting of NMF, dimethyl sulfoxide (DMSO), formamide, N,N′-dimethylpropyleneurea, dimethylacetamide, N-methylpyrrolidone, gamma-butyrolactone, propylene carbonate, acetonitrile, 2-methoxyethanol, methyl acetate, ethyl acetate, ethyl formate, methyl formate, tetrahydrofuran, diethyl ether, tetrahydrothiophene, and diethyl sulfide.

The precursor 16P of the sulfide semiconductor 16 contains a material that is crystallized in a process described below to become the sulfide semiconductor 16. The precursor 16P may include, for example, xanthate; in particular, in the present embodiment, a case where the precursor 16P is ethyl zinc xanthate depicted in FIG. 5 will be described as an example. Since the precursor 16P contains xanthate, the dispersibility of the precursor 16P in the solvent 18M is improved.

However, the precursor 16P is not limited to xanthate, and may include, for example, at least one kind of metal acetate, metal nitrate or metal halide salt as a metal source, and thiourea, N-methylthiourea, 1,3-dimethylthiourea, N,N′-dimethylthiourea, tetramethylthiourea or thioacetamide as a sulfur source. Alternatively, the precursor 16P may contain a metal complex in which thiourea, N-methylthiourea, 1,3-dimethylthiourea, N,N′-dimethylthiourea, tetramethylthiourea, or thioacetamide is coordinated to metal atoms.

The blue quantum dot structure 20B, the green quantum dot structure 20G, and the red quantum dot structure 20R include the blue quantum dot 14B, the green quantum dot 14G, and the red quantum dot 14R, respectively, and ligands 22 coordinated to these quantum dots. The ligand 22 includes, for example, ethyl xanthate and chloro ions as depicted in FIG. 5. The ligand 22 including ethyl xanthate and chloro ions are coordinated to each quantum dot, and thus, the dispersibility of each quantum dot in the solvent 18M is improved together with the precursor 16P. Therefore, the quantum dot dispersion 18 more efficiently reduces aggregation of the quantum dots in the solvent 18M.

### Method for Manufacturing Light-emitting Device: Applying and Drying of Quantum Dot Dispersion

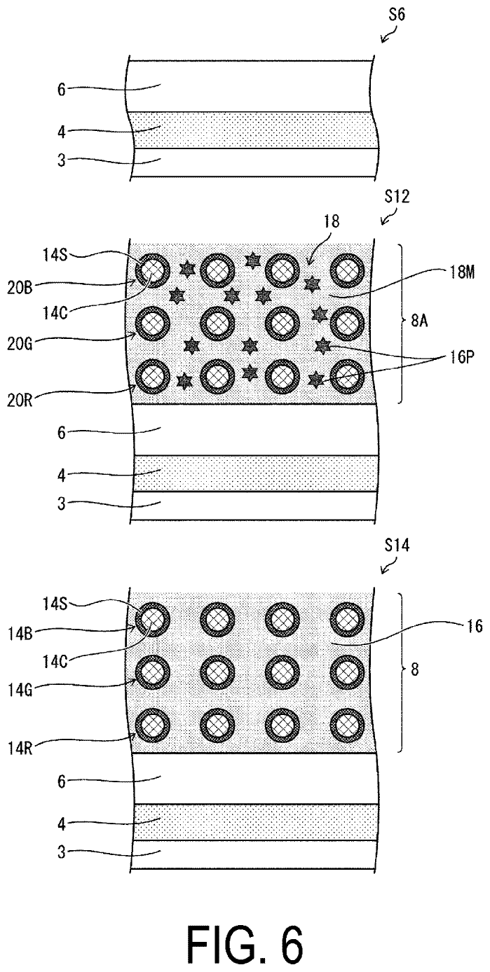

Next, application of the quantum dot dispersion 18 and a method for forming the light-emitting layer 8 from the quantum dot dispersion 18 will be described in detail with reference to FIG. 6. FIG. 6 is a process cross-sectional view for describing the method for forming the light-emitting layer 8.

As illustrated in FIG. 6, at the time of completion of step S6, the substrate 3, the anode 4, and the hole transport layer 6 are formed. Here, in the present embodiment, the quantum dot dispersion 18 prepared in step S8 and step S 10 is applied onto the hole transport layer 6 (step S12). In other words, step S12 is a process of applying the quantum dot dispersion 18 onto a substrate that is a layered body including the substrate 3, the anode 4, and the hole transport layer 6. With this, a coating layer 8A including the quantum dot dispersion 18 on the hole transport layer 6 is formed.

The quantum dot dispersion 18 may be applied by, for example, a spin coating method in which the quantum dot dispersion 18 is applied onto the hole transport layer 6 while rotating the layered body from the substrate 3 to the hole transport layer 6. Alternatively, the quantum dot dispersion 18 may be applied using an existing thin film forming method such as an ink-jet method.

Subsequent to the application of the quantum dot dispersion 18, the layered body from the substrate 3 to the coating layer 8A is heated at a temperature of 80° C. to 500° C. for one minute or longer to dry the coating layer 8A (step S14). As the coating layer 8A is dried, a film in which the quantum dots are dispersed in the precursors 16P is formed. Further, the precursor 16P is denatured to form the sulfide semiconductor 16. With this, as illustrated in FIG. 6, the light-emitting layer 8 is formed on the hole transport layer 6.

The precursor 16P may be thermally decomposable, for example, like ethyl zinc xanthate. In this case, in step S14, for example, the layered body may be heated at 100° C. to volatilize the solvent 18M, and then the layered body may be heated to 175° C. to thermally decompose the precursor 16P, thereby achieving the crystallization. In step S14, the precursor 16P is thermally decomposed to reduce the precursor 16P remaining in the light-emitting layer 8, thereby reducing the influence of the precursor 16P on the light emission of the light-emitting layer 8. When the precursor 16P is thermally decomposable, the temperature required for the thermal decomposition of the precursor 16P can be measured by thermogravimetric analysis of the precursor 16P.

In the present embodiment, the precursor 16P may be denatured to a sulfide by irradiating the precursor 16P with light. In this case, for example, the layered body is irradiated with light having a wavelength of 365 nm for one minute to thermally decompose the precursor 16P, thereby crystallizing the precursor 16P.

The ethyl xanthate contained in the ligand 22 may also be decomposed by heating in step S14. In this case, the ethyl xanthate contained in the ligand 22 is unlikely to affect the light emission of the light-emitting layer 8. The chloro ions contained in the ligands 22 may remain around the quantum dots.

The ligand 22 containing ethyl xanthate and chloro ions is coordinated to each of the blue quantum dot 14B, the green quantum dot 14G, and the red quantum dot 14R in the quantum dot dispersion 18. Because of this, the dispersibility of the quantum dots with respect to the solvent 18M is high, and the quantum dots are unlikely to precipitate in the quantum dot dispersion 18. In addition, the occurrence of aggregation of the quantum dots accompanying the reaction of the precursor 16P on the surfaces of the quantum dots is suppressed, and the dispersibility of the quantum dots is maintained for a long period of time.

Furthermore, when the drying of the solvent 18M of the quantum dot dispersion 18 progresses from step S12 through step S14, the concentration of the quantum dots in the quantum dot dispersion 18 increases. However, in the quantum dot dispersion 18, the ligands 22 are coordinated to the respective quantum dots, and thus, a situation in which the quantum dots precipitate before the precursor 16P is deposited on the hole transport layer 6 is suppressed.

Therefore, the light-emitting layer 8 formed in the present embodiment becomes a smoother film in which the blue quantum dots 14B, the green quantum dots 14G, and the red quantum dots 14R are more uniformly dispersed.

In step S14 according to the present embodiment, to form the light-emitting layer 8, the layered body from the anode 4 to the coating layer 8A is heated to 80° C. to 500° C. Accordingly, in order to reduce the deterioration of each layer in step S14, all the layers from the anode 4 to the cathode 12 may be formed of layers of inorganic material.

Method for Manufacturing Light-Emitting Device: after Formation of Electron Transport Layer Next, the electron transport layer 10 is formed (step S16). As described above, the electron transport layer 10 may be formed by, for example, a vacuum deposition method, a sputtering method, a coating formation method using a colloidal solution, or the like. Next, the cathode 12 is formed (step S18). The cathode 12 may be formed by film-forming a conductive material by using, for example, the sputtering method as described above.

As described above, the light-emitting element 2 according to the present embodiment is formed, and the manufacturing process of the light-emitting device 1 is completed. Note that the method for manufacturing the light-emitting device 1 according to the present embodiment may include a step of forming the hole injection layer, the electron injection layer, and the intermediate layer described above. Furthermore, subsequent to step S18, a capping layer or the like may be formed on the cathode 12, thereby forming the capping layer or the like on the light-emitting element 2.

Thus, the light-emitting element 2 manufactured by the above-discussed manufacturing method reduces a difference in intensity of light obtained from the plurality of quantum dots having mutually different luminescent colors while suppressing the decrease in luminous efficiency, as described above. In the method for manufacturing the light-emitting element 2 described above, the light-emitting layer 8 is formed by crystallizing the precursor 16P by heating the quantum dot dispersion 18. Therefore, according to the above manufacturing method, the light-emitting layer 8, in which the spaces between the quantum dots are more densely filled with the sulfide semiconductor 16, can be formed, and the light-emitting layer 8 configured to further reduce the energy transfer between the quantum dots can be formed.

### Second Embodiment

### Display Device

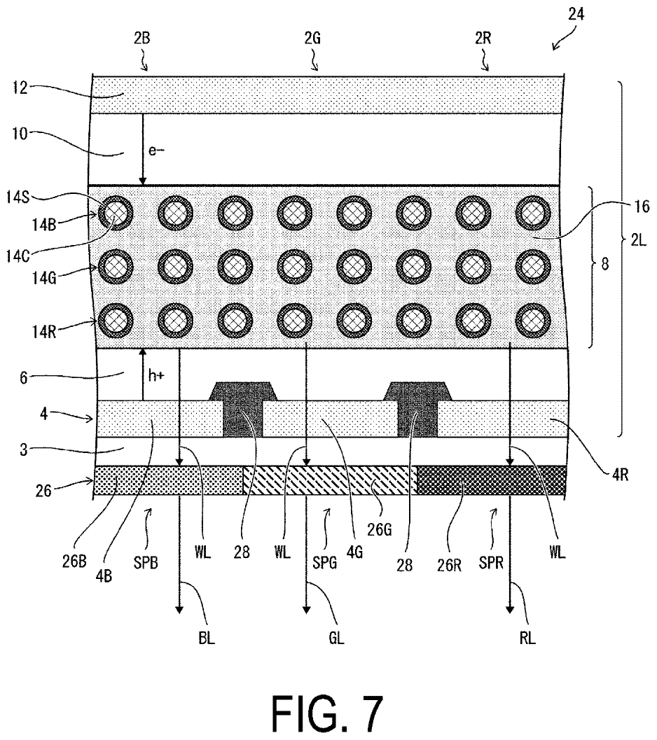

FIG. 7 is a schematic side cross-sectional view illustrating a display device 24 according to the present embodiment. The display device 24 includes a light-emitting element layer 2L, a substrate 3, a color filter 26, and banks 28. Further, the display device 24 includes a blue subpixel SPB, a green subpixel SPG, and a red subpixel SPR in an array form in a plan view of the substrate 3.

The light-emitting element layer 2L according to the present embodiment includes a light-emitting element 2B overlapping the blue subpixel SPB, a light-emitting element 2G overlapping the green subpixel SPG, and a light-emitting element 2R overlapping the red subpixel SPR in a plan view of the substrate 3. The light-emitting element layer 2L includes an anode 4, a hole transport layer 6, a light-emitting layer 8, an electron transport layer 10, and a cathode 12 in this order from the side of the substrate 3.

In particular, in the present embodiment, the anode 4 includes an anode 4B overlapping the blue subpixel SPB, an anode 4G overlapping the green subpixel SPG, and an anode 4R overlapping the red subpixel SPR. Thus, the light-emitting element 2B, the light-emitting element 2G, and the light-emitting element 2R include the anode 4B, the anode 4G, and the anode 4R, respectively, as the anode 4.

The layers from the hole transport layer 6 to the cathode 12 included in the light-emitting element layer 2L have the same configurations as the layers from the hole transport layer 6 to the cathode 12 according to the previous embodiment except that the layers are formed in common to a plurality of the subpixels. In other words, each of the light-emitting element 2B, the light-emitting element 2G, and the light-emitting element 2R includes the hole transport layer 6, the light-emitting layer 8, the electron transport layer 10, and the cathode 12 according to the previous embodiment.

The substrate 3 according to the present embodiment includes, for each subpixel, a TFT configured to individually drive each of the anode 4B, the anode 4G, and the anode 4R. Accordingly, the display device 24 individually drives each of the light-emitting element 2B, the light-emitting element 2G, and the light-emitting element 2R, and individually controls white light WL from the portions of the light-emitting layer 8 overlapping the respective subpixels in a plan view of the substrate 3. The substrate 3 may include a driver, a terminal, and the like for individually driving a plurality of the TFTs based on an input signal.

The color filter 26 includes a blue filter 26B overlapping the blue subpixel SPB, a green filter 26G overlapping the green subpixel SPG, and a red filter 26R overlapping the red subpixel SPR in a plan view of the substrate 3. The blue filter 26B, the green filter 26G, and the red filter 26R mainly transmit light of wavebands of blue light, green light, and red light, respectively. The color filter 26 may include typically known various materials such as a color resist.

The color filter 26 is located at a position on a side of a light-emitting direction of each light-emitting element, related to each of the light-emitting element 2B, the light-emitting element 2G, and the light-emitting element 2R. For example, the color filter 26 is formed on a side of the substrate 3 opposite to a side of the light-emitting element 2B, the light-emitting element 2G, and the light-emitting element 2R. However, the color filter 26 is not limited thereto, and may be formed between the substrate 3 and the light-emitting element layer 2L. In addition, in a case where the light-emitting direction of the light-emitting element 2B, the light-emitting element 2G, and the light-emitting element 2R is a direction from the light-emitting layer 8 to the cathode 12, the color filter 26 may be formed on the upper face of the cathode 12.

With the above configuration, the white light WL from the light-emitting layer 8 of each of the light-emitting elements 2B, 2G, and 2R is irradiated to the blue filter 26B, the green filter 26G, and the red filter 26R, and only the light having specific wavelengths passes through the filters. Therefore, the display device 24 extracts blue light BL, green light GL, and red light RL transmitted through the color filter 26 from the blue subpixel SPB, the green subpixel SPG, and the red subpixel SPR, respectively.

As described above, the display device 24 performs full-color display by individually controlling the intensities of the blue light BL from the blue subpixel SPB, the green light GL from the green subpixel SPG, and the red light RL from the red subpixel SPR.

The banks 28 are formed on the substrate 3, and define the anode 4B, the anode 4G, and the anode 4R for each subpixel. In order to reduce the influence of electrical field concentration in the vicinity of end portions of the anode 4B, the anode 4G, and the anode 4R on the drive of the light-emitting elements, the banks 28 may be formed at the positions overlapping the end portions of the anode 4B, the anode 4G, and the anode 4R. The bank 28 may include a resin having optical transparency containing polyimide or the like.

The display device 24 according to the present embodiment may be manufactured by changing part of a process and adding part of a process as compared with the method for manufacturing the light-emitting device 1 according to the previous embodiment. A step of forming the substrate 3 according to the present embodiment may be a process in which, for example, a step of forming a TFT for each subpixel and a driver for driving each TFT is added to step S2 according to the previous embodiment. The anode 4 according to the present embodiment may be formed by, for example, forming a thin film of a conductive material by the above-described method, and then patterning the thin film of the conductive material for each subpixel by dry etching or the like. In the method for manufacturing the display device 24 according to the present embodiment, subsequent to the formation of the anode 4, the banks 28 may be formed by applying and film-forming a photosensitive resin and patterning the thin film of the photosensitive resin by photolithography. The portion from the hole transport layer 6 to the cathode 12 may be formed by the same method as that from step S6 to step S18 according to the previous embodiment except that, subsequent to the formation of the banks 28, each layer is formed in common to a plurality of the subpixels. In the method for manufacturing the display device 24 according to the present embodiment, subsequent to the formation of the light-emitting element layer 2L on the substrate 3, the color filter 26 may be formed by film-forming and patterning a color resist at the opposite side of the substrate 3 to the side of the light-emitting element layer 2L. The color filter 26 may be formed before the light-emitting element layer 2L is formed on the substrate 3.

Each of the light-emitting element 2B, the light-emitting element 2G, and the light-emitting element 2R according to the present embodiment has the same layer structure as the light-emitting element 2 according to the previous embodiment. Therefore, the light-emitting elements 2B, 2G, and 2R each reduce a difference in intensity of light obtained from the plurality of quantum dots having mutually different luminescent colors while suppressing the decrease in luminous efficiency. The display device 24 reduces a difference in light emission intensity between the subpixels and improves the white balance while achieving power saving or a long lifetime.

The display device 24 includes the light-emitting layer 8 common to the light-emitting element 2B, the light-emitting element 2G, and the light-emitting element 2R. This light-emitting layer 8 does not require selective ink-jet-based application or patterning in the forming step. Accordingly, the display device 24 simplifies the manufacturing process, reduces the deterioration of the light-emitting layer 8, and improves the luminous efficiency of each of the light-emitting element 2B, the light-emitting element 2G, and the light-emitting element 2R.

### Third Embodiment

### Another Example of Display Device

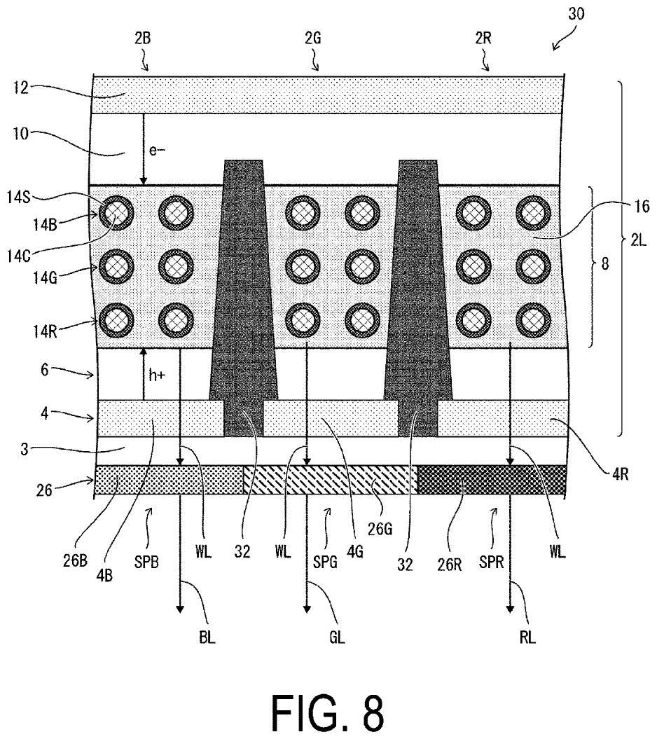

FIG. 8 is a schematic side cross-sectional view illustrating a display device 30 according to the present embodiment. The display device 30 includes banks 32 instead of the banks 28, as compared with the display device 24 according to the previous embodiment. The banks 32 are formed extending from the upper face of a substrate 3 to a halfway height of an electron transport layer 10, as compared with the banks 28 according to the previous embodiment. Thus, the banks 32 partition, in addition to an anode 4, a hole transport layer 6, and a light-emitting layer 8 for each subpixel.

Except for the above points, the display device 30 has the same configuration as the display device 24 according to the previous embodiment. Thus, the display device 30 performs full-color display by individually controlling the intensities of blue light BL from a blue subpixel SPB, green light GL from a green subpixel SPG, and red light RL from a red subpixel SPR.

The hole transport layer 6 and the light-emitting layer 8 according to the present embodiment may be formed by film-forming and patterning a sacrificing layer, film-forming each material including an upper side portion of the sacrificing layer, and patterning each material by removing the sacrificing layer. According to the above forming method, it is unnecessary to repeat the process of patterning the light-emitting layer 8 multiple times, and the number of times of contact between a developing solution and the light-emitting layer is small, so that the deterioration of the hole transport layer 6 and the light-emitting layer 8 may be reduced.

Alternatively, the hole transport layer 6 and the light-emitting layer 8 according to the present embodiment may be formed by applying each material between the banks 32 by an ink-jet method. According to the above forming method, the hole transport layer 6 and the light-emitting layer 8 are not subjected to patterning itself, and thus, the deterioration of the hole transport layer 6 and the light-emitting layer 8 may be further reduced.

Except for the above points, the display device 30 may be manufactured by the same method as the manufacturing method of the display device 24 according to the previous embodiment.

Each of a light-emitting element 2B, a light-emitting element 2G, and a light-emitting element 2R according to the present embodiment has the same layer structure as each of the light-emitting element 2B, the light-emitting element 2G, and the light-emitting element 2R according to the previous embodiment. Therefore, the light-emitting elements 2B, 2G, and 2R each reduce a difference in intensity of light obtained from the plurality of quantum dots having mutually different luminescent colors while suppressing the decrease in luminous efficiency. The display device 30 reduces a difference in light emission intensity between the subpixels and improves the white balance while achieving power saving or a long lifetime.

In the display device 30, since the banks 32 partition the light-emitting layer 8 for each subpixel, the light-emitting element 2B, the light-emitting element 2G, and the light-emitting element 2R each include the individual light-emitting layer 8. With the above configuration, the display device 30 reduces short-circuits between the light-emitting elements, color mixing between the subpixels, and the like.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

1. A light-emitting element comprising:
an anode;
a cathode; and
a light-emitting layer between the anode and the cathode,
wherein the light-emitting layer includes a first quantum dot that emits first light whose light emission central wavelength is a first wavelength, a second quantum dot that emits second light whose light emission central wavelength is a second wavelength longer than the first wavelength, and a semiconductor that encompasses the first quantum dot and the second quantum dot and includes a metal element, and
at least part of the semiconductor is formed as a continuous film having an area of equal to or larger than 1000 nm² in a planar direction orthogonal to a film-thickness direction of the light-emitting layer.

2. The light-emitting element according to claim 1,
wherein the semiconductor includes a metal sulfide semiconductor.

3. The light-emitting element according to claim 2,
wherein the metal sulfide semiconductor includes at least one of zinc sulfide, gallium sulfide, or magnesium sulfide.

4. The light-emitting element according to claim 1,
wherein the semiconductor includes metal halide made of a metal element and a halogen element.

5. The light-emitting element according to claim 1,
wherein the semiconductor includes metal sulfide, and metal halide made of a metal element and a halogen element.

6. The light-emitting element according to claim 1,
wherein the light-emitting layer includes a third quantum dot that emits third light whose light emission central wavelength is a third wavelength longer than the second wavelength.

7. The light-emitting element according to claim 6,
wherein the first light is blue light, the second light is green light, and the third light is red light.

8. The light-emitting element according to claim 7,
wherein with respect to an integral value in a wavelength range of visible light of an optical spectrum of light from the light-emitting layer obtained by applying a voltage to the anode or the cathode, an integral value of an optical spectrum in a wavelength range of the blue light is 5% or more and 30% or less, an integral value of an optical spectrum in a wavelength range of the green light is 55% or more and 75% or less, and an integral value of an optical spectrum in a wavelength range of the red light is 15% or more and 35% or less.

9. The light-emitting element according to claim 8,
wherein of a total number of particles of the first quantum dots, the second quantum dots, and the third quantum dots in the light-emitting layer, the number of particles of the first quantum dots is 5% or more and 30% or less, the number of particles of the second quantum dots is 55% or more and 75% or less, and the number of particles of the third quantum dots is 15% or more and 35% or less.

10. The light-emitting element according to claim 1,
wherein the light-emitting layer includes the semiconductor in an amount of 4% or more and 20% or less by volume.

11. The light-emitting element according to claim 1,
wherein an average distance between the first quantum dot and the second quantum dot adjacent to each other is equal to or longer than 1 nm in the light-emitting layer.

12. The light-emitting element according to claim 1,
wherein the first quantum dot includes a core and a shell covering the core, and a band gap of the semiconductor is larger than a band gap of the core.

13. A light-emitting device comprising:
the light-emitting element according to claim 1.

14. A display device, comprising:
for each of a plurality of subpixels, the light-emitting element according to claim 1; and
a color filter located at a position, relative to the light-emitting element, on a side of a light-emitting direction of the light-emitting element.

15. The display device according to claim 14,
wherein a plurality of the light-emitting elements include the common light-emitting layer.

16. The display device according to claim 14,
wherein the light-emitting elements each include the individual light-emitting layer.

17. (canceled)

18. (canceled)

19. (canceled)
